(19) United States
(12) Patent Application Publication
(10) Pub. No.: US 2026/0156856 A1
(43) Pub. Date: Jun. 4, 2026

(54) GROUP III-V POWER SEMICONDUCTOR DEVICE AND METHOD OF MANUFACTURING SAME

(71) Applicant: DB HiTek Co., Ltd., Bucheon-si (KR)

(72) Inventors: Min Su CHO, Eumseong-gun (KR); Jong Hyun LEE, Eumseong-gun (KR); Woo Chul JEON, Eumseong-gun (KR); Ji Houn JUNG, Eumseong-gun (KR); Ung Bi SON, Eumseong-gun (KR); Jun Hyeok LEE, Eumseong-gun (KR); Dong Hyeok SON, Eumseong-gun (KR)

(21) Appl. No.: 19/066,787

(22) Filed: Feb. 28, 2025

(30) Foreign Application Priority Data
Dec. 2, 2024 (KR) 10-2024-0176206

(51) Int. Cl. H10D 30/47; H10D 30/01; H10D 62/10; H10D 62/60; H10D 62/824; H10D 64/27

(52) U.S. Cl. CPC H10D 30/475; H10D 30/015; H10D 62/102; H10D 62/60; H10D 62/824; H10D 64/411

(57) ABSTRACT

Proposed are a group III-V power semiconductor device and a method of manufacturing the same. More particularly, proposed are a group III-V power semiconductor device in which a low-resistance region is enabled to be formed in a capping layer to be formed below a gate electrode, thereby partially activating a two-dimensional electron gas (2DEG) layer below the capping layer so that the on-resistance characteristics of the device are improved, and a method of manufacturing the same.

### CROSS REFERENCE TO RELATED APPLICATION

The present application claims priority to Korean Patent Application No. 10-2024-0176206, filed Dec. 2, 2024, the entire contents of which is incorporated herein for all purposes by this reference.

### BACKGROUND

### Technical Field

The present disclosure relates to a group III-V power semiconductor device and a method of manufacturing the same. More particularly, the present disclosure relates to a group III-V power semiconductor device in which a low-resistance region is enabled to be formed in a capping layer to be formed below a gate electrode, thereby partially activating a two-dimensional electron gas (2DEG) layer below the capping layer so that the on-resistance characteristics of the device are improved, and to a method of manufacturing the same.

### Description of the Related Art

Nitride-based semiconductors are being applied to high-withstand voltage and high-power semiconductor devices through high electron saturation velocity and wide band gap characteristics. In particular, gallium nitride (GaN) has high breakdown field characteristics and wide band gap characteristics compared to silicon and gallium arsenide (GaAs) and thus exhibits excellent breakdown voltage characteristics when applied to transistors.

In addition, GaN-based devices have high electron mobility and electron saturation velocity compared to silicon-based devices, which are currently commonly available, and therefore, can exhibit high frequency characteristics. In addition, the application of such high electron mobility to GaN-based devices allows for improved on-resistance characteristics, thereby enabling the implementation of low-loss switching devices.

As described above, GaN-based field effect transistors (FETs) are sufficiently advantageous as devices that require high-frequency and high-power characteristics, so ongoing research is in progress. While these GaN-based FETs have been widely studied and developed over the years, there are still several issues regarding device reliability that need to be addressed.

To make such nitride-based semiconductor devices operate in an enhancement mode (E-mode), that is, normally-off operation, a structure in which a p-GaN layer is stacked on a barrier layer may be utilized. For example, to deplete a 2DEG layer in a channel layer, a nitride-based semiconductor device may use a structure in which a p-GaN layer is stacked on a barrier layer on the channel layer. This leads to deactivation of the 2DEG layer immediately below the p-GaN layer and enables the device to be turned on only by applying a positive voltage to a gate electrode.

In this case, to increase the concentration of the activated 2DEG layer (or to reduce the resistance), a method of increasing the Al composition in the barrier layer, which is an AlGaN layer, or increasing the vertical thicknesses of the barrier layer can, for example, be applied. However, due to the limitations of the current technology in increasing the hole concentration in the p-GaN layer, increasing the Al composition in the barrier layer to obtain a certain level of threshold voltage or higher is challenging. In addition, when the vertical thicknesses of the barrier layer are formed to a certain level or larger, the thickness of the barrier layer immediately below the p-GaN layer becomes large, so the normally-off operation of the nitride-based power semiconductor device may not work.

Accordingly, the high resistance below the gate electrode results in increased on-resistance of the device, leading to poor operational characteristics thereof, which may cause an issue where the switching speed of the device is reduced.

FIG. 1 is a cross-sectional view illustrating an existing nitride-based power semiconductor device. Hereinafter, a structure of the existing nitride-based power semiconductor device will be described with reference to FIG. 1.

Referring to FIG. 1, an existing nitride-based power semiconductor device 9 has a structure in which a buffer layer 910, a channel layer 920, and a barrier layer 930 are sequentially stacked on a substrate 909. In addition, a capping layer 940 of a p-GaN layer is formed on the barrier layer 930, and a gate electrode 950 may be formed on the capping layer 940. Furthermore, a source electrode 971 and a drain electrode 973 may be formed while being spaced from each other with the gate electrode 950 disposed therebetween.

In addition, a 2DEG layer A may be formed in the channel layer 920 below the gate electrode 950. In this case, the 2DEG layer A may be completely blocked below the gate electrode 950. Therefore, the high resistance immediately below the gate electrode 950 may result in increased on-resistance of the device 9, leading to poor characteristics thereof.

In this regard, the inventors of the present disclosure have proposed a novel group III-V power semiconductor device and a method of manufacturing the same, the contents of which will be described in detail later.

### DOCUMENTS OF RELATED ART

### Patent Document

Korean Patent Application Publication No. 10-2020-0068745 “High-Electron-Mobility Transistor”

### SUMMARY

The present disclosure, which has been devised to address the above-described issues in the related art, aims to provide a group III-V power semiconductor device in which a low-resistance region is enabled to be formed in a capping layer to be formed below a gate electrode, thereby partially activating a 2DEG layer below the capping layer so that the resistance immediately below the gate electrode is reduced, and therefore, the on-resistance characteristics of the device are improved, and a method of manufacturing the same.

In addition, the present disclosure aims to provide a group III-V power semiconductor device in which a low-resistance region is formed in a capping layer to have a narrower width size than the capping layer so that the on-resistance characteristics of the device are improved while enabling the normally-off operation of the device, and a method of manufacturing the same.

In addition, the present disclosure aims to provide a group III-V power semiconductor device in which a superstructure is enabled to be formed on a capping layer, thereby keeping the superstructure, which will be utilized as a hard mask when forming a low-resistance region, from being removed in the following process and, therefore, preventing the overall process efficiency from being reduced, and a method of manufacturing the same.

In addition, the present disclosure aims to provide a group III-V power semiconductor device in which a superstructure to be formed on a capping layer is enabled to be utilized as a hard mask, thereby preventing a low-resistance region from being formed in a channel layer in advance when forming the low-resistance region in conjunction with an isolation region, and a method of manufacturing the same.

In addition, the present disclosure aims to provide a group III-V power semiconductor device in which a low-resistance region is enabled to be formed in conjunction when forming an isolation film by changing only a mask pattern so that the on-resistance characteristics of the device are improved without additional processes, and a method of manufacturing the same.

The present disclosure may be implemented by embodiments having the following configurations to achieve the above-described objectives.

In one embodiment of the present disclosure, a group III-V power semiconductor device according to the present disclosure is characterized by including: a substrate; a channel layer on the substrate; a barrier layer on the channel layer; a capping layer on the barrier layer; an isolation film surrounding the channel layer; a low-resistance region in the capping layer; a superstructure on the low-resistance region; and a gate electrode on the capping layer, the gate electrode wrapping around a side surface of the superstructure.

In another embodiment of the present disclosure, the group III-V power semiconductor device, according to the present disclosure, is characterized in that the low-resistance region has a top surface that is substantially at the same height as a top surface of the capping layer.

In a further embodiment of the present disclosure, the group III-V power semiconductor device, according to the present disclosure, is characterized in that the low-resistance region is formed in conjunction with the isolation film in the same process.

In a further embodiment of the present disclosure, the group III-V power semiconductor device, according to the present disclosure, is characterized in that the low-resistance region includes the same material as the isolation film, the same material being doped at a lower concentration in the low-resistance region than that in the isolation film.

In a further embodiment of the present disclosure, the group III-V power semiconductor device, according to the present disclosure, is characterized in that the low-resistance region is disposed substantially around the center along a first direction in the capping layer.

In a further embodiment of the present disclosure, the group III-V power semiconductor device, according to the present disclosure, is characterized in that a plurality of low-resistance regions is disposed while being spaced apart from each other along a first direction in the capping layer.

In a further embodiment of the present disclosure, the group III-V power semiconductor device, according to the present disclosure, is characterized in that the low-resistance region has a narrower width size along a first direction than the capping layer.

In a further embodiment of the present disclosure, the group III-V power semiconductor device, according to the present disclosure, is characterized in that the low-resistance region has a stripe-type planar shape.

In a further embodiment of the present disclosure, the group III-V power semiconductor device, according to the present disclosure, is characterized in that the low-resistance region has an island-type planar shape.

In a further embodiment of the present disclosure, the group III-V power semiconductor device, according to the present disclosure, is characterized in that the superstructure is an oxide film or a metal film.

In a further embodiment of the present disclosure, a group III-V power semiconductor device, according to the present disclosure, is characterized by including: a substrate; a channel layer on the substrate; a barrier layer on the channel layer; a capping layer on the barrier layer; an isolation film surrounding the channel layer; a low-resistance region in the capping layer, the low-resistance region having a lower hole concentration than the capping layer; a superstructure on the low-resistance region, the superstructure having a planar pattern corresponding to the low-resistance region; and a gate electrode on the capping layer, the gate electrode wrapping around a side surface of the superstructure, wherein the gate electrode has one or more protrusions protruding downwardly from a bottom surface and being in contact with a side wall of the superstructure.

In a further embodiment of the present disclosure, the group III-V power semiconductor device, according to the present disclosure, is characterized by further including an insulation material layer disposed between the gate electrode and the superstructure.

In a further embodiment of the present disclosure, the group III-V power semiconductor device, according to the present disclosure, is characterized in that the insulation material layer is disposed between a plurality of protrusions of the gate electrode.

In a further embodiment of the present disclosure, the group III-V power semiconductor device, according to the present disclosure, is characterized by further including an insulation film covering the capping layer and the barrier layer, wherein the insulation material layer has a top surface that is disposed higher than a top surface of the insulation film.

In a further embodiment of the present disclosure, the group III-V power semiconductor device, according to the present disclosure, is characterized by further including a first 2DEG layer in the channel layer, below the low-resistance region, wherein the first 2DEG layer is disposed to overlap with the gate electrode along a vertical direction.

In a further embodiment of the present disclosure, the group III-V power semiconductor device, according to the present disclosure, is characterized by further including: a source electrode and a drain electrode that are spaced from each other with the gate electrode disposed therebetween; and a second 2DEG layer disposed in the channel layer, between the gate electrode and the drain electrode, wherein the second 2DEG layer has a higher concentration than the first 2DEG layer.

In one embodiment of the present disclosure, a method of manufacturing a group III-V power semiconductor device, according to the present disclosure, is characterized by including the following steps: sequentially forming a buffer layer, a channel layer, and a barrier layer on a substrate; forming a doped layer doped with a first conductivity type on the barrier layer; forming a superstructure on the doped layer; forming a capping layer by etching the doped layer; forming a low-resistance region in the capping layer, the low-resistance region having a narrower width size along a first direction than the capping layer; forming an isolation film to wrap around the barrier layer; and forming a gate electrode on the capping layer.

In another embodiment of the present disclosure, the method of manufacturing the group III-V power semiconductor device, according to the present disclosure, is characterized in that the step of forming the low-resistance region includes a step of forming the low-resistance region by performing an ion implantation process utilizing the superstructure as a hard mask, wherein the low-resistance region is formed in conjunction with the isolation film through the ion implantation process.

In a further embodiment of the present disclosure, the method of manufacturing the group III-V power semiconductor device, according to the present disclosure, is characterized in that the superstructure is an oxide film or a metal film.

In a further embodiment of the present disclosure, the method of manufacturing the group III-V power semiconductor device, according to the present disclosure, is characterized in that the gate electrode surrounds the superstructure along the first direction.

The present disclosure has the following effects based on the above-described configurations.

The present disclosure has an effect of enabling a low-resistance region to be formed in a capping layer to be formed below a gate electrode, thereby partially activating a 2DEG layer below the capping layer so that the resistance immediately below the gate electrode is reduced and, therefore, the on-resistance characteristics of the device are improved.

In addition, the present disclosure has an effect of forming a low-resistance region in the capping layer to have a narrower width size than the capping layer so that the on-resistance characteristics of the device are improved while enabling the normally-off operation of the device.

In addition, the present disclosure derives an effect of enabling a superstructure to be formed on a capping layer, thereby keeping the superstructure, which will be utilized as a hard mask when forming the low-resistance region, from being removed in the following process and, therefore, preventing the overall process efficiency from being reduced.

In addition, the present disclosure shows an effect of enabling the superstructure to be formed on the capping layer to be utilized as a hard mask, thereby preventing the low-resistance region from being formed in the channel layer in advance when forming the low-resistance region in conjunction with an isolation region.

Furthermore, the present disclosure shows an effect of enabling the low-resistance region to be formed in conjunction when forming the isolation film by changing only a mask pattern so that the on-resistance characteristics of the device are improved without additional processes.

In the meantime, it is further stated that even when not explicitly mentioned herein, the effects hereinafter expected by the technical features of the present disclosure and potential effects thereof are treated as those described herein of the present disclosure.

### BRIEF DESCRIPTION OF THE DRAWINGS

FIG. 1 is a cross-sectional view illustrating an existing nitride-based power semiconductor device;

FIG. 2 is a plan view illustrating a group III-V power semiconductor device according to one embodiment of the present disclosure;

FIGS. 3 and 4 are cross-sectional views along the line AA′ according to a first embodiment of the group III-V power semiconductor device based on FIG. 2;

FIGS. 5 and 6 are cross-sectional views along the line AA′ according to a second embodiment of the group III-V power semiconductor device based on FIG. 2; and

FIGS. 7 to 16 are cross-sectional views illustrating a method of manufacturing a group III-V power semiconductor device according to one embodiment of the present disclosure.

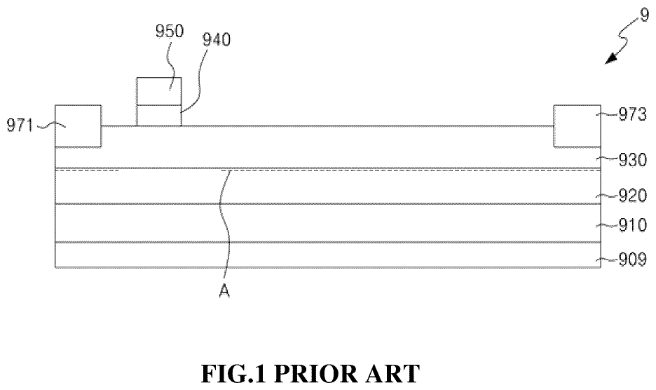

### DETAILED DESCRIPTION

Hereinafter, embodiments of the present disclosure will be described in more detail with reference to the attached drawings. The embodiments of the present disclosure may be modified in various forms, and the scope of the present disclosure should not be construed as being limited to the following embodiments but should be construed on the basis of the appended claims. In addition, these embodiments are only provided for reference to more completely describe the present disclosure to those of ordinary skill in the art to which the present disclosure pertains.

Hereinafter, it should be noted that when one component (or layer) is described as being disposed on another component (or layer), one component may be disposed directly on another component, or another component(s) or layer(s) may be disposed between the components. In addition, when one component is expressed as being directly disposed on or above another component, no other component(s) are disposed between the components. Furthermore, being disposed “on”, “on an upper portion of”, “on a lower portion of”, “above”, “below”, “on one (first) side of”, or “on one side surface of” a component implies a relative positional relationship.

In addition, terms such as first, second, and the like may be used to describe various items, such as various elements, regions, and/or portions, but these items are not limited by such terms.

It should also be noted that when certain embodiments are implementable otherwise, certain processes may be performed in an order that differs from that described below. For example, two processes described sequentially may be substantially performed simultaneously or inversely.

Furthermore, a conductivity type or a doped region of components may be defined as “p-type” or “n-type” depending on the characteristics of main carriers, but this is only for the benefit of description, and the technical idea of the present disclosure is not limited as exemplified. For example, the more general term “first conductivity type” or “second conductivity type” will be used hereinafter for the “p-type” or “n-type”. In this case, the first conductivity type refers to the p-type, and the second conductivity type refers to the n-type.

It should also be understood that the terms “high concentration” and “low concentration” that express doping concentrations of impurity regions may refer to relative doping concentrations of one component and other components.

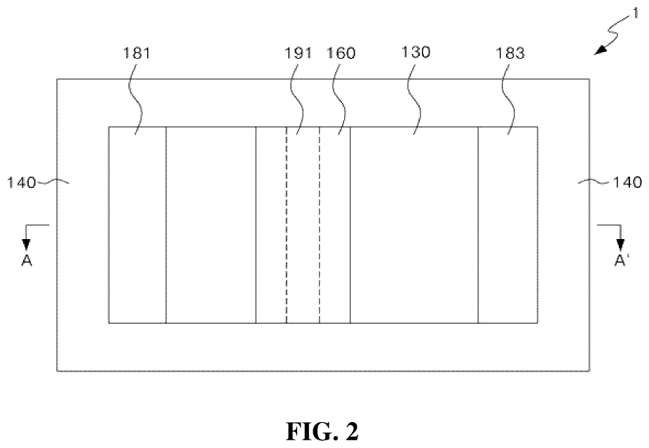

In addition, in the plan view illustrated in FIG. 2, an x-axis direction (the direction in which a gate electrode and a drain electrode are spaced apart) is set as a “first direction”, while a y-axis direction (the direction orthogonal to the x-axis direction on the same horizontal plane) is set as a “second direction”.

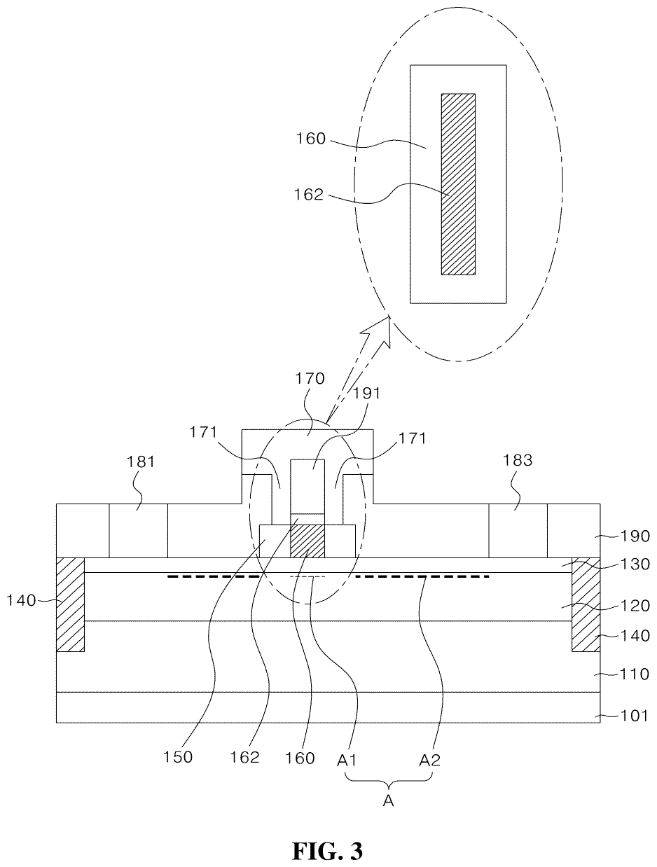

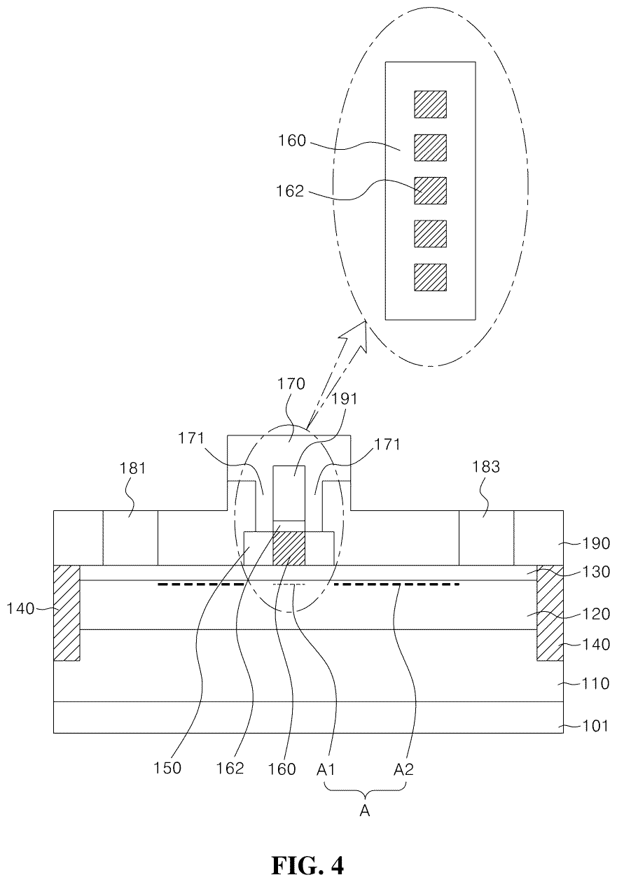

FIG. 2 is a plan view illustrating a group III-V power semiconductor device according to one embodiment of the present disclosure, and FIGS. 3 and 4 are cross-sectional views along the line AA′ according to a first embodiment of the group III-V power semiconductor device based on FIG. 2. It should be noted that in the plan view illustrated in FIG. 2, an insulation film is omitted.

Hereinafter, a group III-V power semiconductor device 1, according to the first embodiment of the present disclosure, will be described in detail with reference to the attached drawings.

Referring to FIGS. 2 to 4, the present disclosure relates to the group III-V power semiconductor device 1. More particularly, the present disclosure relates to the group III-V power semiconductor device 1 in which a low-resistance region 160 is enabled to be formed in a capping layer 150 to be formed below a gate electrode 170, thereby partially activating a 2DEG layer A below the capping layer 150 so that the resistance immediately below the gate electrode 170 is reduced and, therefore, the on-resistance characteristics of the device 1 are improved.

First, the group III-V power semiconductor device 1, according to the first embodiment of the present disclosure, may include a substrate 101. The substrate 101, which is a substrate for growth, may, for example, be a silicon substrate, but there are no limitations. Other examples thereof may include a sapphire substrate, a GaN substrate, or a SiC substrate. In the present disclosure, an example where the substrate 101 is a silicon substrate is to be described.

In addition, a buffer layer 110 may be formed on the substrate 101. The buffer layer 110 may be formed, for example, by growing AlN on the substrate 101 to a predetermined thickness. Alternatively, the buffer layer 110 may have a form in which a single layer of GaN or AlGaN or a composite layer of one or more of the foregoing GaN and AlGaN is grown, but there are no limitations. Such a buffer layer 110 may be a structure configured to prevent stress caused by differences in lattice constants and thermal expansion coefficients of the substrate 101 and a channel layer 120 to be described later. The buffer layer 110 may also be doped with impurities such as C and/or Fe. However, it should be noted that the buffer layer 110 is not an essential component of the present disclosure.

The channel layer 120 is formed to have a predetermined thickness on the substrate 101, more preferably on the buffer layer 110, and may, for example, be made of a semiconductor layer based on a nitride such as GaN. In addition, a barrier layer 130 is formed to have a predetermined thickness on the channel layer 120 and may, for example, be a semiconductor layer based on a nitride such as AlGaN. However, the scope of the present disclosure is not limited thereto. Such channel layer 120 and barrier layer 130 are preferably formed of nitride-based semiconductor layers that differ from each other. On the basis of such a structure, the 2DEG layer A may be formed near the interface between the channel layer 120 and the barrier layer 130. In this case, the density and mobility of the 2DEG layer A may be controlled by adjusting the Al and Ga contents in the barrier layer 130. In addition, the 2DEG layer A may be formed in the channel layer 120.

In addition, the channel layer 120 and the barrier layer 130 may be surrounded by an isolation film 140. The isolation film 140, which is configured to define an active region of the group III-V power semiconductor device 1 according to one embodiment of the present disclosure, may, for example, have a planar ring-like shape or a planar polygonal shape surrounding the channel layer 120 and the barrier layer 130. However, there are no particular limitations. Such an isolation film 140 may be formed through ion implantation of one or more elements of Ar, N, O, Si, and H into the channel layer 120 and the barrier layer 130. In one example, the isolation film 140 may be formed such that the upper portion thereof is disposed on the surface of the barrier layer 130 while the lower portion thereof is disposed in the buffer layer 110. However, the scope of the present disclosure is not limited thereto.

In addition, the capping layer 150 may be formed on the barrier layer 130. The capping layer 150, which is configured to be formed between the barrier layer 130 and the gate electrode 170, causes depletion of the 2DEG layer A immediately below the gate electrode 170 to enable the normally-off operation of the device 1. In addition, the capping layer 150 preferably has a positive polarity. When such a capping layer 150 is formed to a predetermined or larger thickness, the gate electrode 170 and the 2DEG layer A become more distant, resulting in a longer response time. In contrast, when formed to a predetermined or smaller thickness, it is difficult to achieve the normally-off operation of the device 1. Therefore, the thickness thereof is preferably formed at a suitable level, which is, for example, in the range of 10 nm to 1000 nm, but there are no limitations.

In addition, the capping layer 150 may be formed by growing p-GaN and may, for example, be formed by doping GaN with Mg. The capping layer 150 may also include a material formed by a difference in composition ratio based on a combination of x and y in an AlₓIn_{y}Ga_{1-x-y} material (x+y<1).

In addition, the low-resistance region 160 may be formed in the capping layer 150. The low-resistance region 160 is configured to cause a partial region in the capping layer 150 to lose the unique function thereof, thereby activating the 2DEG layer A below the low-resistance region 160 to reduce the resistance below the gate electrode 170. Such a low-resistance region 160 may be formed through ion implantation of one or more elements of Ar, N, O, Si, and H into the capping layer 150. In one example, the ion implantation of H element into the capping layer 150 may passivate the capping layer 150 made of Mg-doped GaN. Therefore, the hole concentration in the capping layer 150 may be reduced, and a first 2DEG layer A1 having a relatively low concentration may be formed below the low-resistance region 160. In other words, the first 2DEG layer A1 below the low-resistance region 160 may have a lower concentration than a second 2DEG layer A2 adjacent thereto but may improve the on-resistance characteristics of the device 1 by activating at least a portion of the 2DEG layer A below the gate electrode 170.

In another example, the ion implantation of elements such as Ar and/or N into the capping layer 150 may cause lattice damage in the capping layer 150 based on p-GaN, thereby reducing the polarization charge of the capping layer 150. On this basis, the first 2DEG layer A1 having a relatively low concentration may be formed below the low-resistance region 160. In addition, the ion implantation of H element into the capping layer 150 at high energy and/or high concentration may cause lattice damage in the capping layer 150.

In addition, the low-resistance region 160 preferably has a narrower width size along the first direction than the capping layer 150. Therefore, the normally-off operation of the device 1 may be enabled while improving the on-resistance characteristics by the low-resistance region 160. In one example, the low-resistance region 160 may be formed substantially around the center of the capping layer 150 along the first direction. In contrast, when the low-resistance region 160 is formed off-center in the capping layer 150 along the first direction, it may become difficult to maintain the threshold voltage of the device 1. The expression “formed substantially around the center” above is understood to mean formed around the center of the capping layer 150 within the alignment error range of a mask pattern to be utilized when forming the low-resistance region 160.

In addition, the low-resistance region 160 preferably has a thickness along the vertical direction that is the same as or larger than that of the capping layer 150. In one example, the low-resistance region 160 may have an upper portion that is disposed substantially at the same height as the upper portion of the capping layer 150. In addition, the low-resistance region 160 may have a lower portion that is substantially at the same height as the lower portion of the capping layer 150 or is disposed in the barrier layer 130. In one example, the lower portion of the low-resistance region 160 may be disposed substantially at the same height as the interface between the channel layer 120 and the barrier layer 130. However, the scope of the present disclosure is not limited thereto.

According to one embodiment, the low-resistance region 160 may be formed between both ends of the capping layer 150 along the first direction. In one example, the low-resistance region 160 may be disposed around the center of the capping layer 150 along the first direction, in the capping layer 150. In addition, the low-resistance region 160 may be elongated uninterruptedly along the second direction. Thus, the low-resistance region 160 may be formed in a stripe pattern (see FIG. 3). Alternatively, a single low-resistance region 160 may be formed between both ends of the capping layer 150 along the first direction while the upper portions thereof are spaced apart from each other along the second direction. Thus, the low-resistance region 160 may be formed in a single-column island pattern (see FIG. 4).

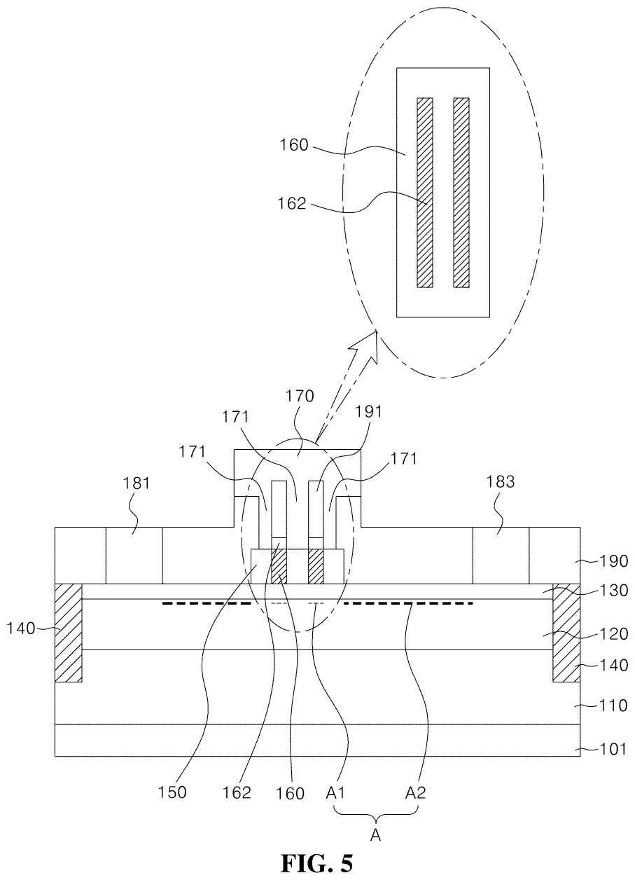

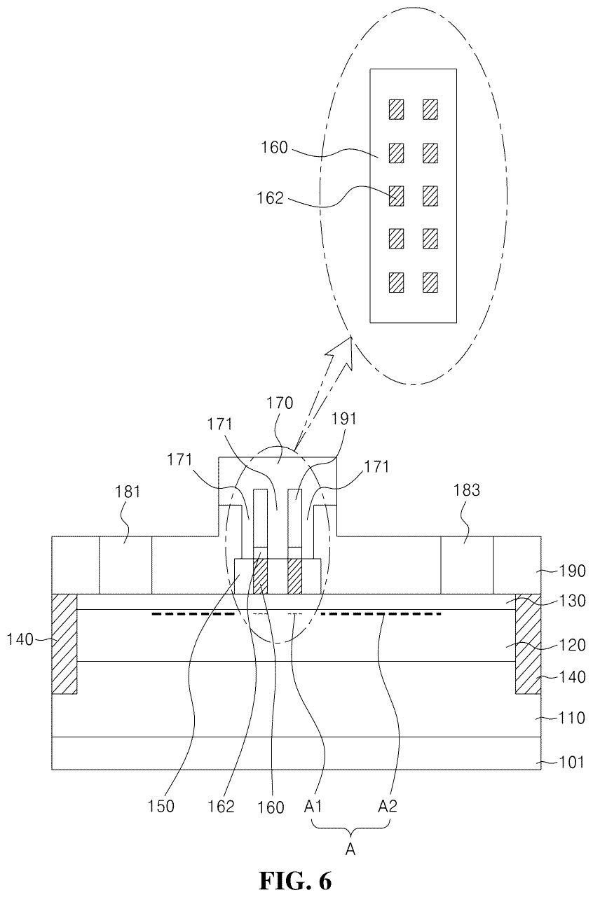

FIGS. 5 and 6 are cross-sectional views along the line AA′ according to a second embodiment of the group III-V power semiconductor device based on FIG. 2.

Alternatively, according to another embodiment, a plurality of low-resistance regions 160 may be formed in the capping layer 150 while being spaced apart from each other along the first direction. In addition, the low-resistance region 160 may be elongated uninterruptedly along the second direction. Thus, the plurality of low-resistance regions 160 may be formed in a stripe pattern (see FIG. 5). In contrast, the low-resistance regions 160 may be spaced from each other along the first direction while being spaced apart from each other along the second direction in each column. Thus, the low-resistance regions 160 may also be formed in a multi-column island pattern (see FIG. 6).

By forming the low-resistance region 160 in the capping layer 150 as described above, the hole concentration in the capping layer 150 on the side where the low-resistance region 160 is formed can be reduced. In addition, the low-resistance region 160 preferably includes the same material as the isolation film 140 and is more preferably made of the same material as the isolation film 140. Furthermore, the low-resistance region 160 is preferably formed substantially in conjunction with the isolation film 140 in the process of forming the isolation film 140. Such a low-resistance region 160 is formed through an ion implantation process utilizing a superstructure 162 as a hard mask, which will be described later, and thus preferably has a lower doping concentration of the same element than the isolation film 140. For example, during the ion implantation process of one or more elements of Ar, N, O, Si, and H, the doping concentrations of these materials in the low-resistance region 160 may be lower than those in the isolation film 140.

In addition, referring to FIGS. 2 to 4, the superstructure 162 may further be formed on the capping layer 150. The superstructure 162, which is configured to be in contact with the top surface of the capping layer 150, may be formed to overlap with the low-resistance region 160 along the vertical direction in the capping layer 150. This superstructure 162 is configured as the hard mask during the ion implantation process for forming the low-resistance region 160. The low-resistance region 160 is formed in conjunction with the isolation film 140 in the same process. Thus, when the superstructure 162, configured as the hard mask, is not utilized, the low-resistance region 160 may extend through the barrier layer 130 and also be formed even in the channel layer 120.

In addition, one embodiment of the present disclosure is characterized in that the process of removing the hard mask is not needed because the hard mask is left in place without being removed after forming the low-resistance region 160, so the overall process efficiency is prevented from being reduced. Furthermore, the superstructure 162 may reduce the leakage current of the gate electrode 170 in the device 1. Such a superstructure 162 may have a planar shape or pattern that corresponds substantially to the low-resistance region 160. In addition, the number of superstructures 162 formed on the single capping layer 150 may correspond to that of low-resistance regions 160.

Such a superstructure 162 may, for example, include or be made of any one of an oxide film, a nitride film, an oxynitride film, and a metal film. In addition, an insulation material layer 191 may be disposed between the superstructure 162 and the gate electrode 170 along the vertical direction. The insulation material layer 191, which is configured to be left on the superstructure 162 when forming an insulation film 190, has a top surface that is disposed higher than the top surface of the insulation film 190. However, it should be noted that the insulation material layer 191 is not an essential component of the present disclosure.

In addition, the gate electrode 170 may be formed on the capping layer 150. The gate electrode 170 may, for example, be formed of a single layer or composite layer made of various metals, such as Ti and Pd. The depletion layer of such a gate electrode 170 may penetrate the barrier layer 130, reaching the channel layer 120 and thus blocking the 2DEG layer A to enable the normally-off operation of the device 1.

In addition, the gate electrode 170 may be formed in a structure such that a lower portion thereof wraps around the hard mask 162 on the capping layer 150 along the first direction. For example, to form the low-resistance region 160 in the capping layer 150, the superstructure 162 that functions as the hard mask is formed on the capping layer 150. Then, an ion implantation process may be performed on the capping layer 150 to form the low-resistance region 160. The gate electrode 170 is formed thereafter. In this case, the superstructure 162 may be left in place on the low-resistance region 160 without being removed, as described above.

Thus, the gate electrode 170 may have a plurality of protrusions 171 protruding downwardly from the bottom surface thereof along the first direction. The plurality of protrusions 171 may be spaced from each other along the first direction, and each protrusion may be in contact with a side wall of the superstructure 162 along the first direction. The number of such protrusions 171 formed may correspond to those in the form of the low-resistance regions 160 and the superstructures 162. For example, when a single superstructure 162 is formed along the first direction, the gate electrode 170 may have a pair of protrusions 171 protruding downwardly from the bottom surface thereof while being spaced from each other. In addition, when two superstructures 162 are spaced from each other along the first direction, the gate electrode 170 may have three protrusions 171 that are spaced from each other. Thus, the gate electrode 170 may have a shape that is similar to a roughly arcuate cross-sectional shape.

In addition, a source electrode 181 and a drain electrode 183 may be formed on the barrier layer 130 while being spaced from each other. In some cases, the source electrode 181 and the drain electrode 183 may be formed such that the lower portions thereof are disposed in the barrier layer 130, on the interface between the barrier layer 130 and the channel layer 120, in the channel layer 120, or on the barrier layer 130. However, there are no particular limitations.

The source electrode 181 and the drain electrode 183 may be disposed in the active while being spaced from each other with the gate electrode 170 disposed therebetween. Such source electrode 181 and drain electrode 183, which are ohmic contact regions, may, for example, have a square cross-sectional shape or a stepped cross-sectional shape. However, the scope of the present disclosure is not limited by any particular examples. In addition, the source electrode 181 and the drain electrode 183 may, for example, include a single layer or composite layer made of various metals capable of ohmic contact, such as Ti, Au, and Al. However, there are no particular limitations.

In addition, the insulation film 190 may be formed on the barrier layer 130. Furthermore, the insulation film 190 is preferably formed such that one side thereof is in contact with the gate electrode 170 while not covering the top surfaces of the source electrode 181 and the drain electrode 183. Such an insulation film 190 may be made of an electrically insulating material, for example, Al₂O₃, but there are no particular limitations, and may also include any oxide film, nitride film, or the like.

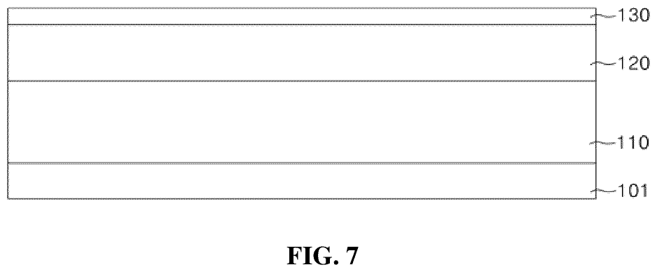

FIGS. 7 to 16 are cross-sectional views illustrating a method of manufacturing a group III-V power semiconductor device according to one embodiment of the present disclosure.

Hereinafter, a method of manufacturing a group III-V power semiconductor device 1, according to one embodiment of the present disclosure, will be described in detail with reference to the attached drawings.

Referring to FIG. 7, a buffer layer 110, a channel layer 120, and a barrier layer 130 may first be formed sequentially on a substrate 101. The substrate 101, which is a substrate for growth as described above, may be any one of a silicon substrate, a sapphire substrate, a GaN substrate, and a SiC substrate, but the description in the present disclosure is based on one example being a silicon substrate. The buffer layer 110 may be formed on the substrate 101 and under the channel layer 120, for example, by growing an AlN layer to a predetermined thickness. In addition, the channel layer 120 to be formed on the buffer layer 110 is a semiconductor layer based on a nitride such as GaN, and the barrier layer 130 is a semiconductor layer based on a nitride such as AlGaN. By electrons accumulated at the interface between the channel layer 120 and the barrier layer 130, a 2DEG layer A may be formed (see FIG. 3).

For a detailed description, piezoelectric polarization may occur at the interface between the channel layer 120 and the barrier layer 130, for example, due to differences in lattice constants of GaN and AlGaN. In this case, the piezoelectric polarization effect and the spontaneous polarization effect of the channel layer 120 and the barrier layer 130 may function, thereby generating two-dimensional electron gas with a high electron concentration at the interface between the two configurations.

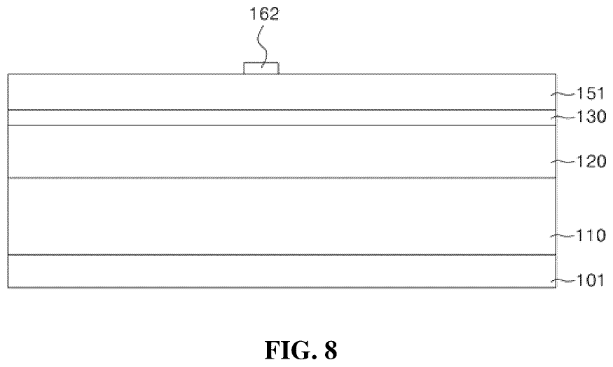

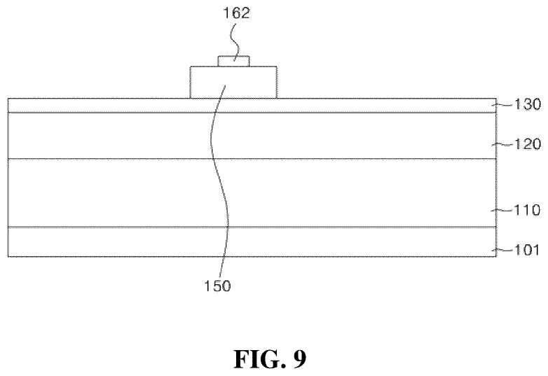

In addition, a capping layer 150 may be formed on the barrier layer 130. Referring to FIG. 8, to this end, a doped layer 151, for example, in which a GaN layer is grown with the first conductivity type, may be first formed on the barrier layer 130. Furthermore, a superstructure 162 that functions as a hard mask may be formed on the doped layer 151. The superstructure 162 may be completed by depositing an oxide film, a nitride film, an oxynitride film, or a metal film on the doped layer 151 and then performing an etching process. Such a superstructure 162 may be left on the capping layer 150 after the capping layer 150 is completed. Referring to FIG. 9, a mask pattern (not shown) may be utilized afterward to etch the doped layer 151, thereby completing the capping layer 150.

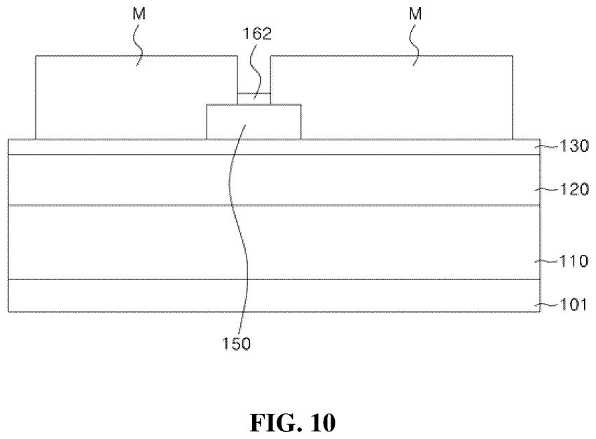

Referring to FIG. 10, the mask pattern M may then be formed on the barrier layer 130. The mask pattern M may have a shape that covers the capping layer 150 but does not cover at least one side of the top surface of the superstructure 162. In addition, the mask pattern M may be formed such that the top surface of the barrier layer 130 on the side where an isolation film 140 is to be formed is prevented from being covered. Thus, at least one side of the top surface of the superstructure 162 may be exposed.

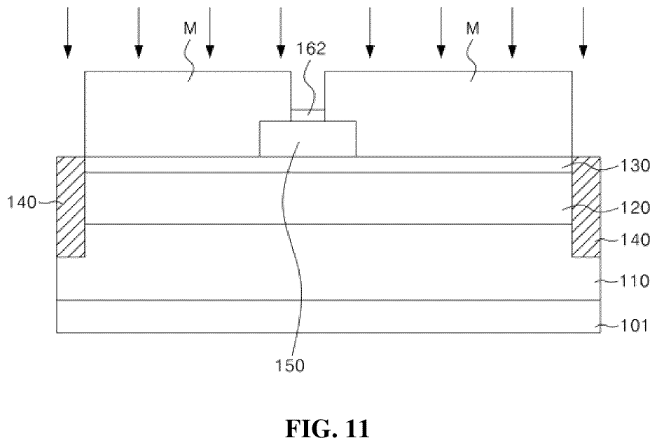

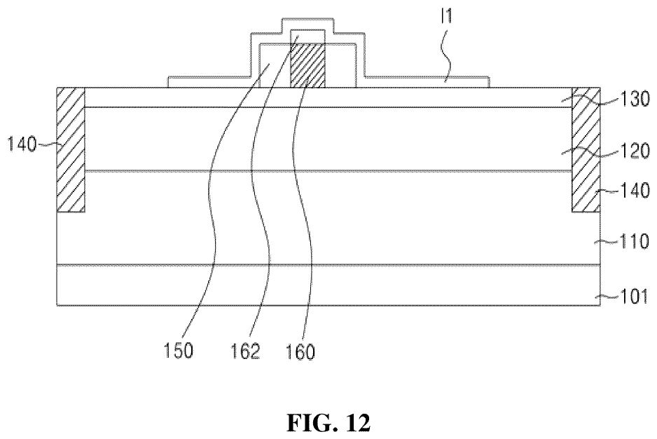

Referring to FIGS. 11 and 12, an ion implantation process may then be performed utilizing the mask pattern M. By this process, the isolation film 140 and a low-resistance region 160 may be formed. As described above, the isolation film 140 and the low-resistance region 160 may be formed through ion implantation of one or more elements of Ar, N, O, Si, and H. In addition, the low-resistance region 160 utilizes the superstructure 162 as a hard mask and thus may have a lower doping concentration of one or more elements of Ar, N, O, Si, and H than the isolation film 140.

Referring to FIG. 12, a first insulation layer I1 may then be formed on the barrier layer 130. The first insulation layer I1 may be formed to cover the capping layer 150 and the superstructure 162. Then, the first insulation layer I1 on the side where a source electrode 181 and a drain electrode 183 are to be formed may be etched. The first insulation layer I1 may be made of an electrically insulating material and may, for example, include an oxide film, a nitride film, or an oxynitride film.

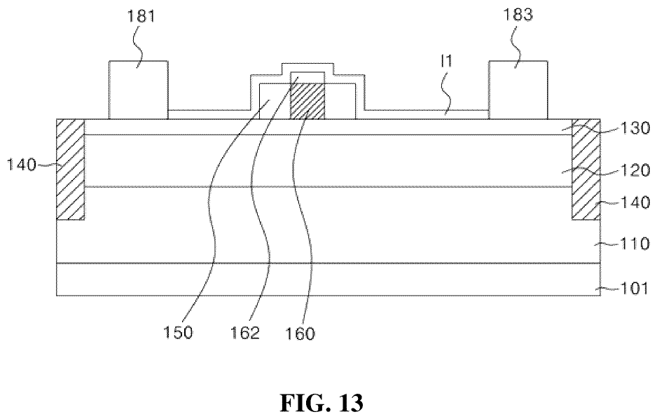

Referring to FIG. 13, the source electrode 181 and the drain electrode 183 may then be formed along the first direction with the capping layer 150 disposed therebetween. The source electrode 181 and the drain electrode 183 may be formed by depositing a metal layer (not shown) and performing an etching process.

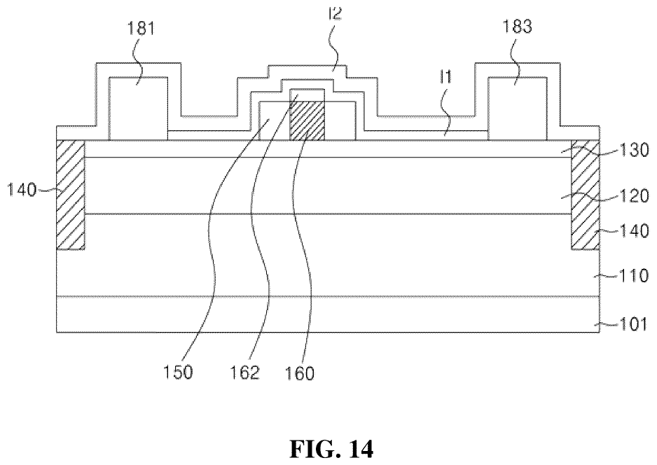

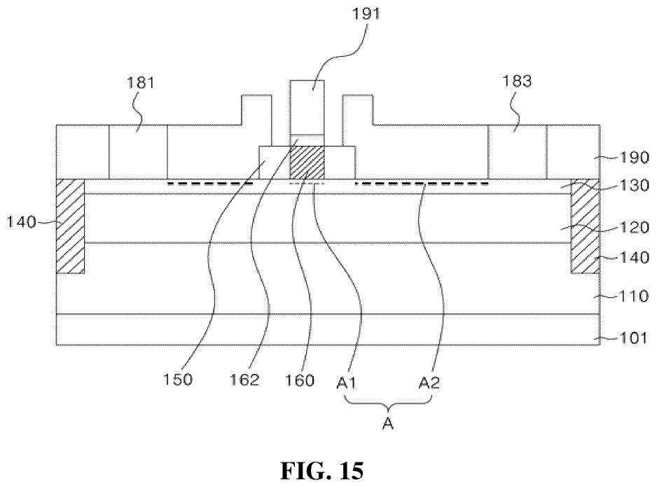

Referring to FIG. 14, a second insulation layer I2 may then be formed on the first insulation layer I1. The second insulation layer I2 may be made of an electrically insulating material and may include an oxide film, a nitride film, or an oxynitride film. Also, referring to FIG. 15, one side of the second insulation layer I2 may be etched so that one side of the top surface of the capping layer 150 is exposed. In the etching process, the top surfaces of the source electrode 181 and the drain electrode 183 may also be exposed. By this process, an insulation film 190 and, in some cases, an insulation material layer 191 may be completed. Such an insulation material layer 191 may be removed in conjunction when etching the second insulation layer I2.

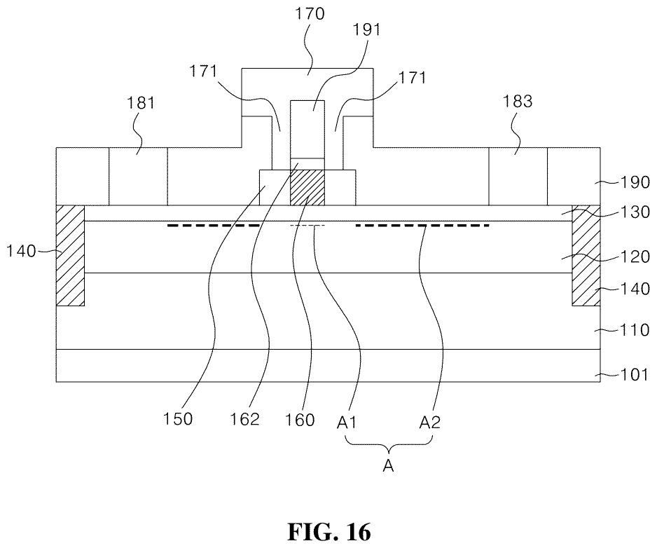

Referring to FIG. 16, a gate electrode 170 may then be formed by depositing the metal layer on the second insulation layer I2 and performing an etching process. The detailed description above is illustrative of the present disclosure. In addition, the description above shows and describes preferred embodiments of the present disclosure, and the present disclosure can be used in various other combinations, modifications, and environments. In other words, changes or modifications are possible within the scope of the concept of the disclosure disclosed herein, the scope equivalent to the written disclosure, and/or the scope of skill or knowledge in the art to which the present disclosure pertains. The above-described embodiments describe the best state for implementing the technical idea of the present disclosure, and various changes required in the specific application field and use of the present disclosure are possible. Therefore, the detailed description of the present disclosure above is not intended to limit the present disclosure to the embodiments disclosed herein.

What is claimed is:

1. A group III-V power semiconductor device comprising:
a substrate;
a channel layer disposed on the substrate;
a barrier layer disposed on the channel layer;
a capping layer disposed on the barrier layer;
an isolation film surrounding the channel layer;
a low-resistance region disposed in the capping layer;
a superstructure disposed on the low-resistance region; and
a gate electrode disposed on the capping layer, the gate electrode wrapping around a side surface of the superstructure.

2. The group III-V power semiconductor device of claim 1, wherein the low-resistance region has a top surface that is substantially at a same height as a height of a top surface of the capping layer.

3. The group III-V power semiconductor device of claim 1, wherein the low-resistance region is formed in conjunction with the isolation film in a same process.

4. The group III-V power semiconductor device of claim 1, wherein the low-resistance region comprises a material same as a material of the isolation film, the material of the low-resistance region being doped at a concentration lower than a concentration of the material of the isolation film.

5. The group III-V power semiconductor device of claim 1, wherein the low-resistance region is disposed substantially around a center along a first direction in the capping layer.

6. The group III-V power semiconductor device of claim 1, wherein a plurality of low-resistance regions is disposed while being spaced apart from each other along a first direction in the capping layer.

7. The group III-V power semiconductor device of claim 1, wherein the low-resistance region has a narrower width size along a first direction than the capping layer.

8. The group III-V power semiconductor device of claim 1, wherein the low-resistance region has a stripe-type planar shape.

9. The group III-V power semiconductor device of claim 1, wherein the low-resistance region has an island-type planar shape.

10. The group III-V power semiconductor device of claim 1, wherein the superstructure is an oxide film or a metal film.

11. A group III-V power semiconductor device comprising:
a substrate;
a channel layer disposed on the substrate;
a barrier layer disposed on the channel layer;
a capping layer disposed on the barrier layer;
an isolation film surrounding the channel layer;
a low-resistance region disposed in the capping layer, the low-resistance region having a hole concentration lower than a hole concentration of the capping layer;
a superstructure disposed on the low-resistance region, the superstructure having a planar pattern corresponding to the low-resistance region; and
a gate electrode disposed on the capping layer, the gate electrode wrapping around a side surface of the superstructure,
wherein the gate electrode has one or more protrusions protruding downwardly from a bottom surface of the gate electrode and being in contact with a side wall of the superstructure.

12. The group III-V power semiconductor device of claim 11, further comprising:
an insulation material layer disposed between the gate electrode and the superstructure.

13. The group III-V power semiconductor device of claim 12,
wherein the gate electrode has a plurality of protrusions, and
wherein the insulation material layer is disposed between the plurality of protrusions of the gate electrode.

14. The group III-V power semiconductor device of claim 12, further comprising:
an insulation film covering the capping layer and the barrier layer,
wherein the insulation material layer has a top surface that is disposed higher than a top surface of the insulation film.

15. The group III-V power semiconductor device of claim 11, further comprising:
a first two-dimensional electron gas (2DEG) layer disposed in the channel layer, below the low-resistance region,
wherein the first 2DEG layer is disposed to overlap with the gate electrode along a vertical direction.

16. The group III-V power semiconductor device of claim 15, further comprising:
a source electrode and a drain electrode that are spaced from each other with the gate electrode being disposed therebetween; and
a second 2DEG layer disposed in the channel layer, between the gate electrode and the drain electrode,
wherein the second 2DEG layer has a concentration higher than a concentration of the first 2DEG layer.

17. A method of manufacturing a group III-V power semiconductor device, the method comprising:
sequentially forming a buffer layer, a channel layer, and a barrier layer on a substrate;
forming a doped layer doped with a first conductivity type on the barrier layer;
forming a superstructure on the doped layer;
forming a capping layer by etching the doped layer;
forming a low-resistance region in the capping layer, the low-resistance region having a narrower width size along a first direction than the capping layer;
forming an isolation film to wrap around the barrier layer; and
forming a gate electrode on the capping layer.

18. The method of claim 17,
wherein the forming of the low-resistance region comprises:
forming the low-resistance region by performing an ion implantation process utilizing the superstructure as a hard mask,
wherein the low-resistance region is formed in conjunction with the isolation film through the ion implantation process.

19. The method of claim 17, wherein the superstructure is an oxide film or a metal film.

20. The method of claim 17, wherein the gate electrode surrounds the superstructure along the first direction.
